(19) United States
(12) Patent Application Publication
(10) Pub. No.: US 2012/0199182 A1
(43) Pub. Date: Aug. 9, 2012

(54) SOLAR CELL DEVICE

(75) Inventors: John E. Drummond, Poughkeepsie, NY (US); Thomas J. Fleischman, Poughkeepsie, NY (US); Scott W. Pollyea, Loveland, CO (US); Roger A. Quon, Rhinebeck, NY (US)

(73) Assignee: INTERNATIONAL BUSINESS MACHINES CORPORATION, Armonk, NY (US)

(21) Appl. No.: 13/020,057

(22) Filed: Feb. 3, 2011

(51) Int. Cl. H01L 31/0232

(52) U.S. Cl. 136/252; 136/257

(57) ABSTRACT

A solar cell device includes a solar cell. The solar cell includes a first light-capturing element configured to receive photonic energy. The solar cell device also includes a device interface for communicatively coupling an electrically chargeable device with the solar cell to receive electrical energy converted by the solar cell from the photonic energy. The solar cell device also includes a second light-capturing element for receiving and providing photonic energy as a supplemental source of energy to the solar cell.

### BACKGROUND

The present invention relates to solar cell technology, and more specifically, to a solar cell device with improved energy output.

Enhancing power output for solar cells is an increasing issue with solar technology. In a typical configuration, solar cell components include various conductive materials that do not absorb or otherwise utilize all of the energy available to them. In other words, current solar cell technology does not utilize the wide spectrum of light waves found in solar energy.

Current techniques for increasing energy output for solar devices include arranging a number of cells in a group or array to form a solar panel. The solar cells are interconnected using wiring or wire mesh. While these configurations can certainly increase overall power output, there are associated increases in costs associated with them.

In addition, the technology to improve the actual cell efficiency is driving the costs of the solar cell production higher due to advanced or more complex processes involved in these devices.

### SUMMARY

According to one embodiment of the present invention, a solar cell device with enhanced energy output is provided. The solar cell device includes a solar cell having a first light-capturing element configured to receive photonic energy. The solar cell device also includes a device interface for communicatively coupling an electrically chargeable device with the solar cell to receive electrical energy converted by the solar cell from the photonic energy. The solar cell device also includes a second light-capturing element for receiving and providing photonic energy as a supplemental source of energy to the solar cell.

According to another embodiment of the present invention, a method of implementing a solar cell device is provided. The method includes communicatively coupling an electrically chargeable device to a solar cell, the electrically chargeable device configured to receive electrical energy converted by the solar cell from photonic energy captured by a first light-capturing element of the solar cell. The method also includes receiving photonic energy via a second light-capturing element. The method further includes providing the photonic energy received via the second light-capturing element to the solar cell as a supplemental source of energy. The method also includes converting, via the solar cell, the supplemental source of energy to electrical energy.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The foregoing and other features, and advantages of the invention are apparent from the following detailed description, taken in conjunction with the accompanying drawings, in which:

FIG. 1 depicts a block diagram of a solar cell device and chargeable device powered by the solar cell device in an exemplary embodiment;

FIG. 2 depicts a three-dimensional view of the solar cell device of FIG. 1 in one exemplary embodiment;

FIG. 3 depicts a three-dimensional view of the solar cell device of FIG. 1 in another exemplary embodiment;

FIG. 4 depicts a three-dimensional view of the solar cell device of FIG. 1 in a further exemplary embodiment; and

FIG. 5 depicts a flow diagram describing a process for implementing the solar cell device of FIG. 1 in an exemplary embodiment.

### DETAILED DESCRIPTION

Exemplary embodiments of the invention provide enhanced solar cell functionality to solar-powered devices while minimizing costs incurred in deploying solar powered devices. In an exemplary embodiment, the enhanced solar cell functionality is implemented by providing a supplemental source of energy, when needed, for use in combination with a solar cell to maximize the energy output by the solar cell. The solar cell functionality utilizes luminescence substances that work in conjunction with photovoltaic solar cells, as will be described herein.

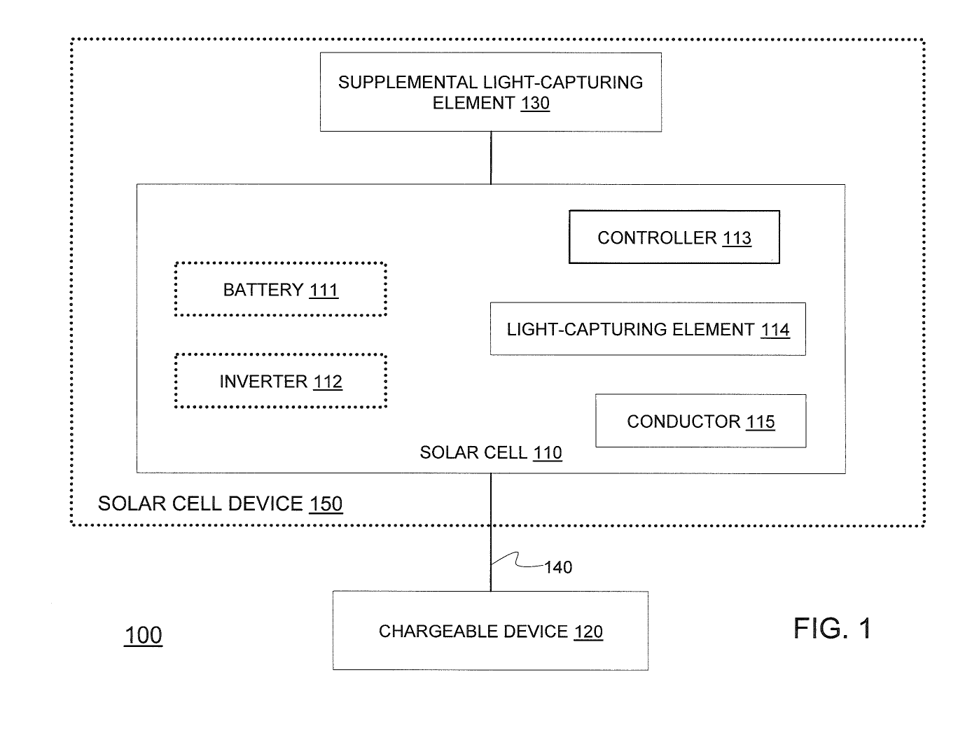

With reference now to FIG. 1, a block diagram depicting a solar cell device 150 and chargeable device 120 powered by the solar cell device (collectively referred to as a “solar-powered device” 100) will now be described in an exemplary embodiment. The solar-powered device 100 includes the solar cell device 150 and chargeable device 120 communicatively coupled by a device interface 140.

The chargeable device 120 may be any electrical device that is capable of being charged using solar cell technology. In an exemplary embodiment, the chargeable device 120 is a lighting apparatus, such as an outdoor light. The solar cell device 150 may include an interface port (not shown) that enables the device interface 140 to transmit electrical power from the solar cell device 150 to the chargeable device 120. The electrical transmission between the solar cell device 150 and the device interface 140 may be implemented using physical wiring or a combination of wireline and wireless technology (e.g., Bluetooth).

In an exemplary embodiment, the solar cell device 150 includes a supplemental light-capturing element 130 and a solar cell 110.

In an exemplary embodiment, the solar cell 110 includes a controller 113, a light-capturing element 114, and one or more conductors 115. The light-capturing element 114 may be a photovoltaic cell (or a combination of cells, such as an array or grouping of panels) formed using a crystalline structure or thin-film structure (e.g., materials such as amorphous silicon, gallium arsenide, copper indium diselenide, and cadmium telluride). In one exemplary embodiment, the light-capturing element 114 is formed of semiconductor material (e.g., silicon). The semiconductor material absorbs a portion of the energy from the sun (i.e., photons), which causes a reaction in the semiconductor material resulting in the movement of electrons therein. The conductors 115 may be implemented to guide this movement of electrons. The conductors 115 may be implemented using conductive terminals or contacts disposed, e.g., at either end of the light-capturing element 114 in order to direct the current (electrons) in the light-capturing element 114 to the chargeable device 120 and, alternatively, to a battery (e.g., battery 111 described below).

The controller 113 monitors the electrical field generated through the solar cell 110 to regulate the amount of current (e.g., voltage) the solar cell 110 may produce. In an exemplary embodiment, the controller 113 may also monitor the electrical field to determine whether a condition is met for utilizing energy from the supplemental light-capturing element 130. The controller 113 may be configured to identify conditions for determining when the solar cell device 150 will use the energy produced by the supplemental light-capturing element 130, as described further herein. The controller 113 may include hardware and/or software elements (e.g., a computer processor and logic) to perform the monitoring described above.

Optionally, the solar cell device 150 may include a battery 111 and an inverter 112. The battery 111 may be implemented for storing excess energy of the solar cell 110 and/or supplemental light-capturing device 130 for later use by the solar cell device 150. The inverter 112 receives direct current from the light-capturing element 114 and converts the direct current to alternating current for use by the chargeable device 120. In an alternative embodiment, the functionality of the inverter 112 may be incorporated directly into the solar cell 110 as a single component.

The supplemental light-capturing element 130 provides a secondary source of energy for the solar cell 110 when one or more conditions have been met. The supplemental light-capturing element 130 may be implemented using chemoluminscence that provide or generate light for the solar cell device 150. Chemoluminescence materials may include, e.g., alkaline earth metal aluminate, coated alkaline earth aluminate, alkaline earth silicate, and zinc sulfide.

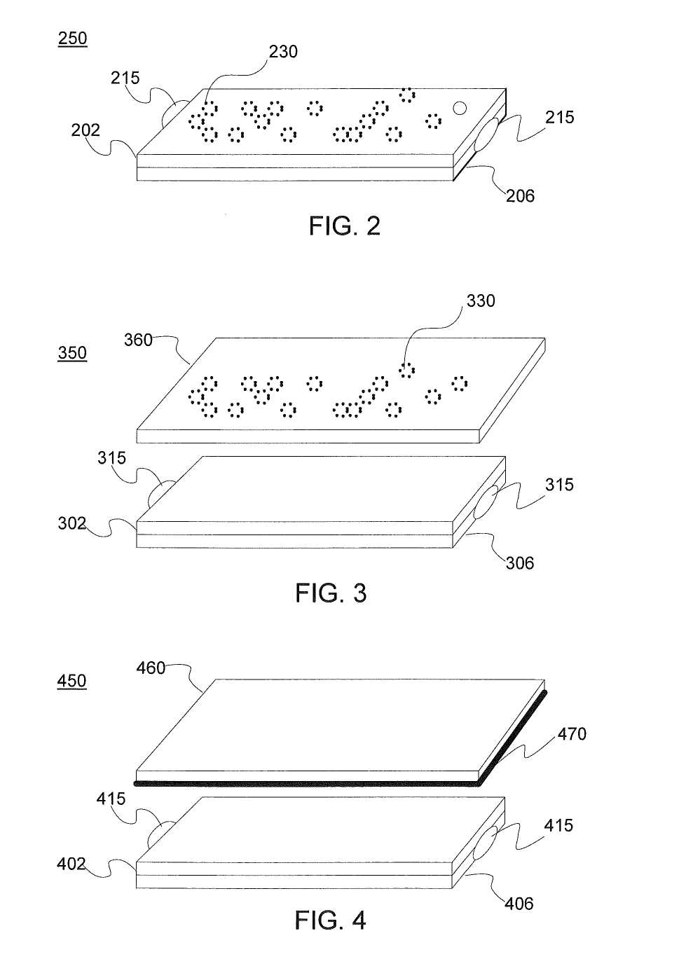

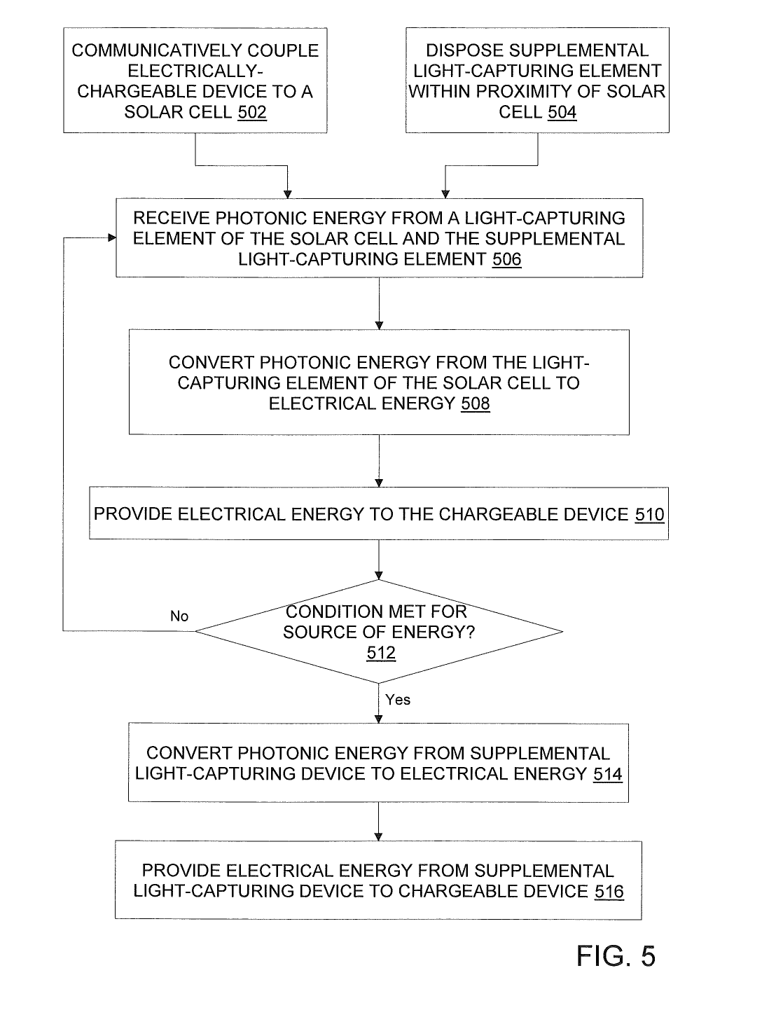

FIG. 2 depicts a three-dimensional view of a solar cell device 250 in an exemplary embodiment; FIG. 3 depicts a three-dimensional view of a solar cell device 350 in an alternative exemplary embodiment; FIG. 4 depicts a three-dimensional view of a solar cell device 450 in a further exemplary embodiment; and FIG. 5 depicts a flow diagram describing a process for implementing a solar cell device in an exemplary embodiment. The exemplary solar cell devices of FIGS. 2-4 and process of FIG. 5 will now be described.

As shown in FIGS. 2-4, solar cell devices 250, 350, and 450, respectively, include a light-capturing layer 202, 302, 402 that respectively include light-capturing elements (e.g., photovoltaic elements). A transparent protective layer (not shown) may be formed over the light-capturing layers 202, 302, 402. Also shown in FIGS. 2-4, solar cell devices 250, 350, and 450 each includes a base layer 206, 306, and 406, which may be formed of a substrate that houses components of the solar cell 110, such as one or more of the battery 111, inverter 112, and controller 113. The light-capturing layers 202, 302, and 402 are respectively disposed on the base layers 206, 306, and 406, respectively. Also shown in FIGS. 2-4 are contacts 215, 315, and 415 disposed on both ends of the solar cell devices 250, 350, and 450, respectively.

The solar cell device 150 may be implemented in various ways as will now be described. At step 502, the electrically chargeable device is communicatively coupled to the solar cell device 150. In an exemplary embodiment, the supplemental light-capturing element is disposed in proximity of the solar cell 110, and in particular within proximity of the light-capturing element 114. As shown in FIG. 2, chemoluminscent particles 230 are disposed directly on the light-capturing layer 206 of the solar cell. The chemoluminescent particles can be sprayed or deposited onto the surface of the solar cell or embedded in any surface layers, typically in the anti-reflective coatings on top of the device. Another layer that can hold the particles is a layer in the solar cell, such as a plastic sheet material with lenses formed thereon to enhance the absorption characteristics). The chemoluminescent particles 230 absorb the light when exposed to the sun and may be used to provide a supplemental source of light to the light-capturing element 114 within the light-capturing layer 202, as described further herein.

In an alternative exemplary embodiment, the chemoluminscent substance 330 is disposed in a transparent layer 360. The transparent layer 330 is then disposed directly on the light-capturing layer 302. The chemoluminscent particles 330 absorb the light when exposed to the sun and may be used to provide a supplemental source of light to the light-capturing element 114 within the light-capturing layer 302, as described further herein.

In an alternative exemplary embodiment, a chemoluminescent paint 470 may be applied to a surface of a substrate 460. The chemoluminscent paint 470 contains chemoluminscent particles, which absorb the light when exposed to the sun. The surface of the substrate 460 in which the chemoluminescent paint 470 has been applied is exposed to the sun and then disposed facing the light-capturing element of the light-capturing layer 402 to provide a supplemental source of light to the light-capturing element 114. If the chemoluminescent paint 470 is used on a substrate 460 for implementing the supplemental light-capturing element 430, the step 504 may be implemented at a later time, e.g., the substrate 460 does not need to be disposed within proximity of the solar cell device 450 until its energy is needed by the solar cell device 450. Thus, in one exemplary embodiment, the supplemental light-capturing element 430 is disposed within proximity of the solar device 450 between steps 512 and 514 described below.

While the supplemental light-capturing element 130 has been described above as being implemented using chemoluminescent materials, it will be understood that other luminescence materials may be applied in order to realize the advantages of the exemplary embodiments herein.

At step 506, photonic energy is received from the light-capturing element 130 of the solar cell 110 and the supplemental light-capturing element 130 (if applicable). At step 508, the solar cell 110 converts the photonic energy to electrical energy (e.g., voltage) and provides the electrical energy to the chargeable device 120 via the device interface 140 at step 510. In one exemplary embodiment, the electrical energy is directly transmitted to the chargeable device 120 from the solar cell 110. In an alternative embodiment, the controller 113 monitors the electrical current field generated through the solar cell 110 and controls the output of electrical current transmitted to the chargeable device 120. In yet a further exemplary embodiment, the controller 113 is configured to monitor the electrical current generated through the solar cell 110 to determine whether a condition is met at step 512. The condition may be a value or range of voltage that establishes a threshold of energy (or amount/percentage of change in energy output), the deviation from which causes the controller 113 to take one or more actions. For example, a disruption or depletion in the current field from the solar cell 110 to the chargeable device 120 results in a drop in voltage output (or lack of voltage output in the case of depletion) to the chargeable device 120. The disruption or depletion may be caused by changes in weather or time of day (e.g., nightfall). If, in response to the monitoring, the energy output reaches a threshold, i.e., condition met, the controller 113 may supplement or replace the source of energy from the light-capturing element 114 to the supplemental light-capturing element 130 at step 514. The electrical energy produced from the supplemental light-capturing element 114 is provided to the chargeable device 120 at step 516. If, however, there is no condition met at step 512, the solar cell 110 continues to convert the light received through the light-capturing element 114 at step 506.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable medium may be a computer readable signal medium or a computer readable storage medium. A computer readable storage medium may be, for example, but not limited to, an electronic, magnetic, optical, electromagnetic, infrared, or semiconductor system, apparatus, or device, or any suitable combination of the foregoing. More specific examples (a non-exhaustive list) of the computer readable storage medium would include the following: an electrical connection having one or more wires, a portable computer diskette, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the context of this document, a computer readable storage medium may be any tangible medium that can contain, or store a program for use by or in connection with an instruction execution system, apparatus, or device.

A computer readable signal medium may include a propagated data signal with computer readable program code embodied therein, for example, in baseband or as part of a carrier wave. Such a propagated signal may take any of a variety of forms, including, but not limited to, electro-magnetic, optical, or any suitable combination thereof. A computer readable signal medium may be any computer readable medium that is not a computer readable storage medium and that can communicate, propagate, or transport a program for use by or in connection with an instruction execution system, apparatus, or device.

Program code embodied on a computer readable medium may be transmitted using any appropriate medium, including but not limited to wireless, wireline, optical fiber cable, RF, etc., or any suitable combination of the foregoing.

Computer program code for carrying out operations for aspects of the present invention may be written in any combination of one or more programming languages, including an object oriented programming language such as Java, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

Aspects of the present invention are described below with reference to flowchart illustrations and/or block diagrams of methods, apparatus (systems) and computer program products according to embodiments of the invention. It will be understood that each block of the flowchart illustrations and/or block diagrams, and combinations of blocks in the flowchart illustrations and/or block diagrams, can be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

These computer program instructions may also be stored in a computer readable medium that can direct a computer, other programmable data processing apparatus, or other devices to function in a particular manner, such that the instructions stored in the computer readable medium produce an article of manufacture including instructions which implement the function/act specified in the flowchart and/or block diagram block or blocks.

The computer program instructions may also be loaded onto a computer, other programmable data processing apparatus, or other devices to cause a series of operational steps to be performed on the computer, other programmable apparatus or other devices to produce a computer implemented process such that the instructions which execute on the computer or other programmable apparatus provide processes for implementing the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

What is claimed is:

1. A solar cell device, comprising:
a solar cell comprising a first light-capturing element configured to receive photonic energy;
a device interface configured to communicatively couple an electrically chargeable device with the solar cell to receive electrical energy converted by the solar cell from the photonic energy; and
a second light-capturing element configured to receive and provide photonic energy as a supplemental source of energy to the solar cell.

2. The solar cell device of claim 1, wherein the second light-capturing element is configured to provide the photonic energy as a supplemental source of energy to the solar cell when a primary source of energy for the solar cell is disrupted, and the solar cell converts the supplemental source of energy to electrical energy.

3. The solar cell device of claim 1, wherein the second light-capturing element is further configured to provide the photonic energy as a supplemental source of energy to the solar cell when a condition is met.

4. The solar cell device of claim 3, further comprising a controller configured to monitor an electrical current of the solar cell, wherein the condition is met when an amount of the electrical current matches a value set by the condition.

5. The solar cell device of claim 1, wherein the second light-capturing element includes a chemical luminescent substance.

6. The solar cell device of claim 5, wherein the chemical luminescent substance is at least one of a(n):
alkaline earth metal aluminate;
coated alkaline earth aluminate;
alkaline earth silicate; and
zinc sulfide.

7. The solar cell device of claim 5, wherein the second light-capturing element further includes a substrate and the chemical luminescent substance is applied to a portion of the substrate;
wherein the portion of the substrate having the chemical luminescent substance is disposed facing the light-capturing element of the solar cell.

8. The solar cell device of claim 5, wherein the second light-capturing element further includes a transparent substrate disposed on the solar cell and the chemical luminescent substance is disposed on the transparent substrate.

9. The solar cell device of claim 5, wherein the chemical luminescent substance is sprayed directly on the solar cell.

10. A method for implementing a solar cell device, comprising:
communicatively coupling an electrically chargeable device to a solar cell, the electrically chargeable device configured to receive electrical energy converted by the solar cell from photonic energy captured by a first light-capturing element of the solar cell;
receiving photonic energy via a second light-capturing element;
providing the photonic energy received via the second light-capturing element to the solar cell as a supplemental source of energy; and
converting, via the solar cell, the supplemental source of energy to electrical energy.

11. The method of claim 10, wherein the second light-capturing element is configured to provide the photonic energy as a supplemental source of energy to the solar cell when a primary source of energy for the solar cell is disrupted, and the solar cell converts the supplemental source of energy to electrical energy.

12. The method of claim 10, wherein the second light-capturing element further implements:
supplying the photonic energy as a supplemental source of energy to the solar cell when a condition is met.

13. The method of claim 12, further comprising:
monitoring an electrical current of the solar cell, wherein the condition is met when an amount of the electrical current matches a value set by the condition.

14. The method of claim 10, wherein the second light-capturing element includes a chemical luminescent substance.

15. The method of claim 14, wherein the chemical luminescent substance is at least one of a(n):
alkaline earth metal aluminate;
coated alkaline earth aluminate;
alkaline earth silicate; and
zinc sulfide.

16. The method of claim 14, wherein the second light-capturing element further includes a substrate, the method further comprising:
applying the chemical luminescent substance to a portion of the substrate;
disposing the portion of the substrate having the chemical luminescent substance to face the light-capturing element of the solar cell.

17. The method of claim 14, wherein the second light-capturing element further includes a transparent substrate, the method further comprising:
disposing the transparent substrate on the solar cell; and
disposing the chemical luminescent substance on the transparent substrate.

18. The method of claim 14, wherein the chemical luminescent substance is sprayed directly on the solar cell.
